(19) United States
(12) Patent Application Publication
(10) Pub. No.: US 2025/0183019 A1
(43) Pub. Date: Jun. 5, 2025

(54) PROGRAMMABLE PRECISION ETCHING

(71) Applicant: Board of Regents, The University of Texas System, Austin, TX (US)

(72) Inventors: Sidlgata V. Sreenivasan, Austin, TX (US); Anant Jain, Austin, TX (US); Paras Ajay, Austin, TX (US)

(21) Appl. No.: 18/842,160

(22) PCT Filed: Feb. 28, 2023
(86) PCT No.: PCT/US2023/014020

§ 371 Date: Aug. 28, 2024

Related U.S. Application Data
(60) Provisional application No. 63/314,725, filed on Feb. 28, 2022.

(51) Int. Cl. H01J 37/32

(52) U.S. Cl. CPC H01J 37/32935; H01J 2237/24578

(57) ABSTRACT

A system and method for thinning a group of two or more dies. An etch gas chemistry is introduced into a plasma generator. Furthermore, plasma is generated using the etch gas chemistry by the plasma generator. The two or more dies placed within an etch chamber are then etched to thin the two or more dies until the two or more dies achieve a desired thickness using the plasma. Furthermore, a spatially variable closed loop control of etch rates of the etching is implemented to provide spatially variable etch rates during the thinning of the two or more dies.

### CROSS REFERENCE TO RELATED APPLICATIONS

This application claims priority to U.S. Provisional Patent Application Ser. No. 63/314,725 entitled “Programmable Precision Etching,” filed on Feb. 28, 2022, which is incorporated by reference herein in its entirety.

### TECHNICAL FIELD

The present invention relates generally to wafer thinning, and more particularly to programmable precision etching to improve the precision of wafer thinning.

### BACKGROUND

Wafer thinning is the process of removing material from the backside of a wafer to a desired final target thickness. The two most common methods of wafer thinning are conventional grind and chemical-mechanical planarization (CMP).

Conventional grinding is an aggressive mechanical process that utilizes a diamond and a resin bonded grind wheel mounted onto a high speed spindle to perform the material removal. The grind recipe dictates the spindle revolutions per minute (RPM), rate of material removal, and the final target thickness of the work piece. Harder materials, such as sapphire, typically require slower feed rates compared to more forgiving materials, such as silicon.

The wafer is positioned on a porous ceramic rotating vacuum chuck with the backside of the wafer facing upwards (towards the grind wheel). Both the grind wheel and wafer chuck rotate during grind. Deionized water is jetted onto the work piece to provide cooling and wash away material particles generated during the grind. A grinding tape is applied to the front side of the wafer to protect the devices from being damaged during thinning.

For conventional grinding, the thinning is a two-step process. The first step is a coarse grind that performs the bulk of the material removal. The second step is a fine grind.

Polishing is the final step in producing a deformation-free surface that is flat, scratch free and mirror-like in appearance. Mechanical polishing requires a separate process and equipment from conventional grinding. Mechanical polishing is a minimal removal process of only 2-3 μm of material and is typically only performed on silicon.

In CMP, abrasive chemical slurry is used with a polishing pad to perform material removal. CMP provides greater planarization compared to mechanical grinding, however, it is considered a “dirtier” and more costly process. The wafers are mounted to a backing film, such as a wax mount, which can be difficult to remove or leave a residue on the front side of the wafer.

CMP does have the advantage of being more forgiving when it comes to processing hard or exotic materials, such as tungsten.

Unfortunately, such processes still need improvement in the precision for wafer thinning.

### SUMMARY

In one embodiment of the present disclosure, a method for thinning a group of two or more dies comprises introducing an etch gas chemistry into a plasma generator. The method further comprises generating a plasma using the etch gas chemistry by the plasma generator. The method additionally comprises etching the two or more dies placed within an etch chamber to thin the two or more dies until the two or more dies achieve a desired thickness using the plasma. Furthermore, the method comprises implementing a spatially variable closed loop control of etch rates of the etching to provide spatially variable etch rates during the thinning of the two or more dies.

In another embodiment of the present disclosure, a system for thinning a group of two or more dies uses the method described above.

The foregoing has outlined rather generally the features and technical advantages of one or more embodiments of the present disclosure in order that the detailed description of the present disclosure that follows may be better understood. Additional features and advantages of the present disclosure will be described hereinafter which may form the subject of the claims of the present disclosure.

### BRIEF DESCRIPTION OF THE DRAWINGS

A better understanding of the present disclosure can be obtained when the following detailed description is considered in conjunction with the following drawings, in which:

FIG. 1 illustrates an architecture for precision substrate thinning (PST) equipment in accordance with an embodiment of the present disclosure;

FIG. 2 is a flowchart of a method for performing substrate thinning using a dry etching process in accordance with an embodiment of the present disclosure;

FIG. 3 is a flowchart of a method for performing substrate planarization using nP3 in accordance with an embodiment of the present disclosure;

FIG. 4 is a flowchart of a method for performing substrate planarization using spatial etch rate control in accordance with an embodiment of the present disclosure;

FIG. 5 is a flowchart of a method for minimizing total thickness variation (TTV) using nP3 in accordance with an embodiment of the present disclosure;

FIG. 6 is a flowchart of a method for minimizing TTV using spatial etch rate control in accordance with an embodiment of the present disclosure;

FIG. 7 illustrates an alternative architecture for PST equipment in comparison to the architecture presented in FIG. 1 in accordance with an embodiment of the present disclosure;

FIG. 8 illustrates an additional alternative architecture for PST equipment in accordance with an embodiment of the present disclosure;

FIG. 9 is a flowchart of a method for performing precision substrate thinning using spatial etch rate control in accordance with an embodiment of the present disclosure;

FIG. 10 depicts the variation in etch rates as a function of temperature for silicon in accordance with an embodiment of the present disclosure;

FIG. 11 illustrates an embodiment of the present disclosure of the thermal actuation sub-system;

FIGS. 12A-12E illustrate the thermal simulation results for quantifying temperature across a die for a given heat input in accordance with an embodiment of the present disclosure;

FIG. 13 is a methodology for the pulse width modulation (PWM) control of the illumination sources used in one instance of the thermal actuation sub-system in accordance with an embodiment of the present disclosure;

FIGS. 14A-14B illustrate simulation and experimental results of the optical lens stack to focus diverging light from a laser diode in accordance with an embodiment of the present disclosure;

FIGS. 15A-15C illustrate substrate scale metrology using single point sensors in accordance with an embodiment of the present disclosure;

FIG. 16 illustrates the inter-die features to address edge non-uniformities in accordance with an embodiment of the present disclosure;

FIG. 17 is a flowchart of a method for generating inter-die features in accordance with an embodiment of the present disclosure;

FIGS. 18A-18F depict the cross-sectional views for generating inter-die features using the steps described in FIG. 17 in accordance with an embodiment of the present disclosure;

FIGS. 19A-19B illustrate an exemplary process for profile correcting using nP3 in accordance with an embodiment of the present disclosure;

FIGS. 20A-20C illustrate a process for profile correction using an intermediate film in accordance with an embodiment of the present disclosure;

FIG. 21 is a flowchart of a method for PST using nP3 in accordance with an embodiment of the present disclosure;

FIG. 22 illustrates a substrate having dies of different thickness in accordance with an embodiment of the present disclosure;

FIG. 23 illustrates an exemplary method for three-dimensional (3D) integration, one of the use cases for PST, in accordance with an embodiment of the present disclosure;

FIG. 24 is a flowchart of an alternative method for generating inter-die features in accordance with an embodiment of the present disclosure; and

FIGS. 25A-25C depict the cross-sectional views for generating inter-die features using the steps described in FIG. 24 in accordance with an embodiment of the present disclosure.

### DETAILED DESCRIPTION

As stated in the Background section, wafer thinning is the process of removing material from the backside of a wafer to a desired final target thickness. The two most common methods of wafer thinning are conventional grind and chemical-mechanical planarization (CMP).

Conventional grinding is an aggressive mechanical process that utilizes a diamond and a resin bonded grind wheel mounted onto a high speed spindle to perform the material removal. The grind recipe dictates the spindle revolutions per minute (RPM), rate of material removal, and the final target thickness of the work piece. Harder materials, such as sapphire, typically require slower feed rates compared to more forgiving materials, such as silicon.

The wafer is positioned on a porous ceramic rotating vacuum chuck with the backside of the wafer facing upwards (towards the grind wheel). Both the grind wheel and wafer chuck rotate during grind. Deionized water is jetted onto the work piece to provide cooling and wash away material particles generated during the grind. A grinding tape is applied to the front side of the wafer to protect the devices from being damaged during thinning.

For conventional grinding, the thinning is a two-step process. The first step is a coarse grind that performs the bulk of the material removal. The second step is a fine grind.

Polishing is the final step in producing a deformation-free surface that is flat, scratch free and mirror-like in appearance. Mechanical polishing requires a separate process and equipment from conventional grinding. Mechanical polishing is a minimal removal process of only 2-3 μm of material and is typically only performed on silicon.

In CMP, abrasive chemical slurry is used with a polishing pad to perform material removal. CMP provides greater planarization compared to mechanical grinding, however, it is considered a “dirtier” and more costly process. The wafers are mounted to a backing film, such as a wax mount, which can be difficult to remove or leave a residue on the front side of the wafer.

CMP does have the advantage of being more forgiving when it comes to processing hard or exotic materials, such as tungsten.

Unfortunately, such processes still need improvement in the precision for wafer thinning.

The embodiments of the present disclosure provide a means for improving the precision for substrate thinning. Embodiments of a process for precision substrate thinning and its equipment are discussed below.

In one embodiment, the equipment can be used for one or more of the following processes: (i) thinning (or mean thickness reduction); (ii) planarizing a surface; and (iii) total thickness variation (TTV) minimization. TTV, as used herein, refers to the difference between the maximum and minimum value of thickness encountered during measurement of one or more contiguous or non-contiguous substrates. Precision substrate thinning (PST) is a combination of the above processes. In one embodiment, PST is used to thin substrates to below one of the following: 50 μm, 10 μm, 5 μm and 1 μm. In one embodiment PST is used to minimize TTV to below one of the following: 200 nm, 100 nm, 50 nm, 25 nm and 10 nm.

In one embodiment, the equipment consists of a process chamber in which the etching gases are introduced and turned into plasma to etch the substrate. A metrology system is described below that measures the thickness and thickness variation across the substrate. A process for correcting TTV and flatness errors is also described below. In one embodiment, such correction is accomplished via the use of a sub-system which generates desired spatially variable etch rates. The spatially variable etch rates along with the metrology sub-system enable the implementation of a closed-loop control scheme to accurately achieve the low thickness and thickness variation desired for precision substrate thinning (PST). In one embodiment, the spatially variable etch rates are determined using an algorithm executed in one or more of the following locations: a local computer, a remote computer and a cloud-based computer.

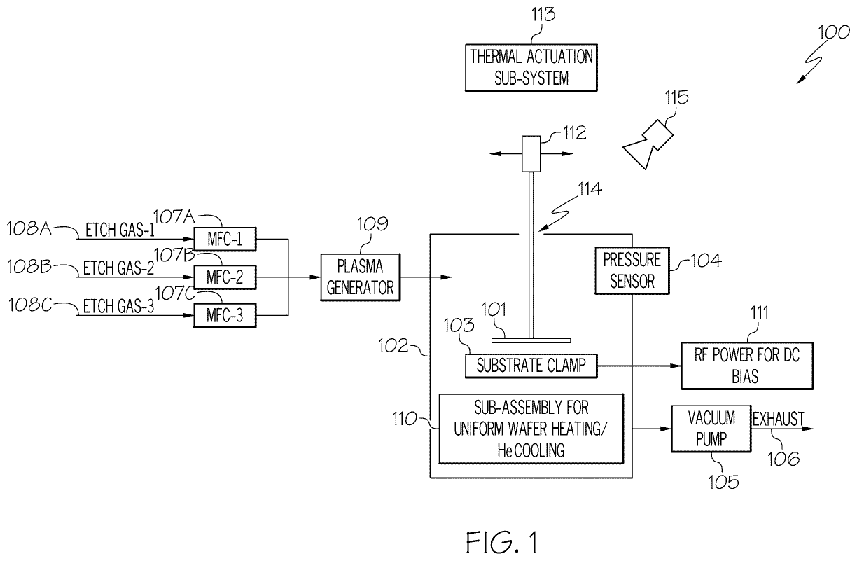

In another embodiment for the correction process, the TTV across the substrate is corrected using the nP3 process. A discussion regarding the nP3 process is provided in International Application No. PCT/US2021/019732, which is incorporated by reference herein in its entirety. In one embodiment, the TTV across the substrate is measured and recorded using the metrology sub-system. nP3 is then used to coat the substrate with a nanometer-precise film of polymer onto the non-uniform substrate. The planarized profile is then etched back into the original substrate. A discussion regarding such equipment is provided below in connection with FIG. 1.

Referring to FIG. 1, FIG. 1 illustrates an architecture for PST equipment in accordance with an embodiment of the present disclosure.

As shown in FIG. 1, a substrate 101 to be etched is placed inside a vacuum chamber 102 (also called an etch chamber) on a substrate clamp 103. In one embodiment, vacuum pressure is controlled by implementing a closed-loop control scheme between a pressure sensor 104 and a vacuum pump 105. The output of vacuum pump 105 is exhaust 106.

In one embodiment, plasma is generated through a remote plasma source, however, other sources as discussed further below can be used. In one embodiment, mass flow controllers (MFC) 107A-107C (identified as “MFC-1,” “MFC-2,” and “MFC-3,” respectively) are used to control the amount of etchant gases 108A-108C (identified as “Etch Gas-1,” “Etch Gas-2,” and “Etch Gas-3,” respectively) injected into the plasma generator 109, which creates the plasma. MFC 107A-107C may collectively or individually be referred to as MFCs 107 or MFC 107, respectively. Etchant gases 108A-108C may collectively or individually be referred to as etchant gases 108 or etchant gas 108, respectively. While FIG. 1 illustrates three MFCs 107 and three etchant gases 108, s any number of MFCs 107 and etchant gases 108 may be utilized.

In one embodiment, a sub-assembly 110 for uniform substrate heating can be present below substrate clamp 103. In one embodiment, substrate clamp 103 is connected to an RF power source 111 to generate a DC bias on substrate 101 to induce a physical etch if needed.

In one embodiment, an optical metrology system can be present above etch chamber 102. In this instance, a single point metrology sensor 112 (e.g., linked color imaging (LCI) sensor) is used to measure the substrate thickness. In one embodiment, a thermal actuation sub-system 113 as described further below is present on top as shown in FIG. 1. The optical metrology sub-system consisting of metrology sensor 112 and thermal actuation sub-system 113 illuminate substrate 101 through a viewport 114. In one embodiment, viewport 114 is made of a material transmissive to light from both sub-systems.

In an alternate embodiment, these sub-systems are present inside etch chamber 102 itself. In one embodiment, the instrument has a thermal camera 115 to monitor the temperature across substrate 101. In one embodiment, a closed-loop control scheme is implemented in which metrology sensor 112 and thermal camera 115 (e.g., IR camera) are used as feedback to control thermal actuation sub-system 113 to induce a spatially variable temperature and hence spatially variable etch rates for reducing thickness variation.

In one embodiment, the PST equipment consists of the following sub-systems: etch chamber 102, plasma generator 109, a DC bias cathode, a thermal actuation sub-system 113, an array of nozzles for implementing spatially varying etch rates, metrology sensor 112, a substrate scale metrology system using large apertures and a substrate scale metrology system using a single spot measuring sensor.

In one embodiment, etch chamber 102 is the process chamber in which etching takes place. In one embodiment, etching gases 108 are introduced in etch chamber 102, where the flow rates of etching gases 108 are controlled through mass flow controllers 107. In one embodiment, etching gases 108 include, but are not limited to, CF₄, CHF₃, SF₆, NF₃, Ar, O₂, Cl₂, N₂, and H₂.

In one embodiment, etch chamber 102 is connected to vacuum pump 105 through a needle valve to control the vacuum pressure. In one embodiment, etch chamber 102 has viewports 114 transmissive to lights from the metrology sub-system and the thermal actuation sub-system, such as thermal actuation sub-system 113.

In one embodiment, plasma generator 109 is configured to generate plasma using various techniques, such as conductively coupled plasma (CCP), inductively coupled plasma (ICP), electron cyclotron resonance (ECR) and remote plasma source (RPS).

In one embodiment, the PST equipment includes a DC bias cathode along with the above plasma sources to induce a physical etch onto substrate 101. In one embodiment, the ratios of power of the DC-bias cathode and plasma generator 109 are adjusted to control the amount of physical versus chemical etching.

In one embodiment, the PST equipment includes a thermal actuation sub-system 113. In one embodiment, such a sub-system 113 includes various sub-systems to create a desired temperature profile on substrate 101, such as a sub-system for uniform thermal actuation, a sub-system for spatially variable thermal actuation and a sub-system for spatially variable thermal actuation using a digital micromirror device (DMD).

In one embodiment, the PST equipment includes a sub-system 113 for uniform thermal actuation. In one embodiment, such a sub-system has thermal actuators for uniform heating of substrate 101 to increase the etch rates. In one embedment, such a sub-system includes resistive heating elements inside etch chamber 102 and below substrate 101, preferably mounted below the plate on which substrate 101 rests (see element 103). In another embodiment, radiative heating lamps are present inside etch chamber 102, such as quartz halogen lamps.

As also discussed above, in one embodiment, thermal actuation sub-system 113 includes the sub-system for spatially variable thermal actuation. In one embodiment, such a sub-system includes high powered laser diodes (LDs) or light emitting diodes (LEDs) as sources of illumination assembled on a printed circuit board (PCB) in a two-dimensional matrix. In one embodiment, such a sub-system includes suitable heat sinks to remove heat from the PCB and LDs/LEDs. In one embodiment, such a sub-system includes a stack of optical components, including, but not limited to, aspheric lenses, cylindrical lenses, reflectors and apertures to focus the divergent light from each of the illumination sources onto substrate 101.

Furthermore, as discussed above, in one embodiment, thermal actuation sub-system 113 includes spatially variable thermal actuation using a DMD (referred to herein as the “DMD sub-system”). In one embodiment, the DMD sub-system includes a high-power laser diode used as a source of irradiation. Furthermore, in one embodiment, the DMD sub-system directs the high power laser onto substrate 101 to generate spatial temperature profiles. In one embodiment, the DMD sub-system includes aspheric lenses, cylindrical lenses and heat sinks for mounting and collimating laser diodes. In one embodiment, the DMD sub-system includes one or more of the above sub-systems mounted on a stationary platform or on a moveable XY stage which can be used to illuminate the entire substrate 101.

In one embodiment, the PST equipment includes a nozzle array for spatially varying the etch rates. In one embodiment, such a sub-system consists of an array of nozzles to inject etching gases 108 inside process chamber 102. The mass flow rates through each of the nozzles can be varied to obtain spatially variable etch rates.

In one embodiment, the PST equipment includes metrology sensor 112. In one embodiment, metrology sensor 112 in the equipment provides information about the thickness and the thickness variation across substrate 101. In one embodiment, the substrate thickness information is provided using sensing techniques, such as laser interferometry, low coherence interferometry, ellipsometry, phase-shifting interferometry, moiré interferometry and spectral interface wafer thickness measurement.

In one embodiment, the PST equipment includes substrate scale metrology using large apertures. In one embodiment, such a substrate scale metrology is configured to measure across the entire substrate 101 using large apertures such that the entire substrate 101 is illuminated and measured. In one embodiment, a technique utilized for performing such illumination and measurement includes linked color imaging (LCI) with hyper-spectral imaging, which utilizes (1) a low-coherence illumination source, such as a superluminescent diode (SLD) to illuminate the entire substrate 101; (2) a reference surface on which light can undergo reflection for interferometry; (3) a hyperspectral camera, which is similar to having a two-dimensional array of single-point spectrometers, where each pixel or each single-point spectrometer corresponds to a specific location on the wafer; and (4) a software algorithm to analyze the resultant spectrogram and evaluate the thickness and/or thickness variation.

In one embodiment, metrology sensor 112 in the equipment provides information about the substrate top profile. In one embodiment, the top profile is measured using sensing techniques, such as laser interferometry, optical emission interferometry and Fizeau interferometry.

In one embodiment, the PST equipment includes a substrate scale metrology system using a single spot measuring sensor. In one embodiment, where the sensing area is smaller than substrate 101, sampling of the entire substrate 101 is implemented using sensors mounted on an XY stage. In one embodiment, such sensors are mounted on an XY stage to scan the entire substrate 101. In one embodiment, instead of a single sensor, an array of sensors are used in different orientations for high throughput. In one embodiment, sampling of the entire substrate 101 is implemented using a variable pitch mechanism (VPM). In one embodiment, one or more sensors discussed above in connection with metrology sensor 112 are mounted on a VPM to scan the entire substrate 101.

A summary of the process implementation is described below.

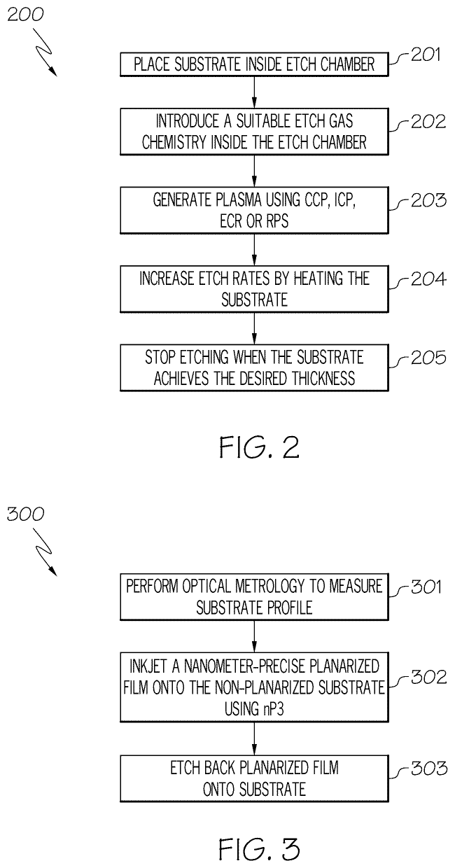

In one embodiment, substrate thinning is performed using a dry etching process described below in connection with FIG. 2. FIG. 2 is a flowchart of a method 200 for performing substrate thinning using a dry etching process in accordance with an embodiment of the present disclosure.

Referring to FIG. 2, in conjunction with FIG. 1, in step 201, substrate 101 is placed inside etch chamber 102.

In step 202, a suitable etch gas chemistry is introduced inside etch chamber 102.

In step 203, plasma is generated to be used in etching using one of the following techniques discussed above, such as CCP, ICP, ECR or RPS.

In step 204, the etch rates are increased by heating substrate 101 using techniques discussed above, such as uniform thermal actuation, spatially variable thermal actuation and spatially variable thermal actuation using the DMD sub-system.

In one embodiment, for difficult to etch materials or materials with high bond strength, including, but not limited to, silicon dioxide, diamond, and gallium nitride, the etch rates can also be increased by inducing a physical sputter component using a DC bias cathode described above.

In step 105, etching is stopped when substrate 101 achieves the desired thickness. In one embodiment, the metrology system using metrology sensor 112 and/or the substrate scale metrology system using large apertures and/or the substrate scale metrology system using a single spot measuring sensor discussed above provide information about substrate thickness, including the mean thickness. In one embodiment, the process discussed above is stopped when substrate 101 achieves the desired thickness. In one embodiment, the thickness information is obtained in real time (for example >10 Hz). In another embodiment, the obtained metrology is performed intermittently. For example, when the etch process is stopped, metrology is subsequently performed following when the etch process is restarted. Such a cycle continues until the desired thickness is achieved.

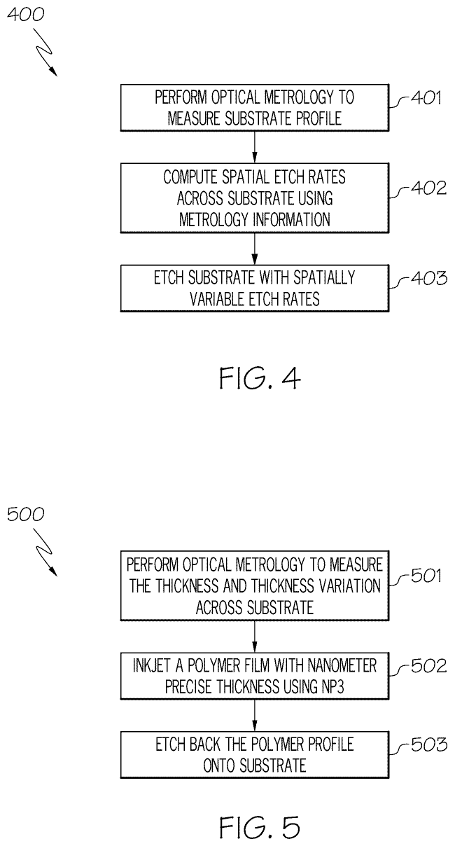

A method for substrate planarization using nP3 is discussed below in connection with FIG. 3.

FIG. 3 is a flowchart of a method 300 for performing substrate planarization using nP3 in accordance with an embodiment of the present disclosure.

Referring to FIG. 3, in conjunction with FIG. 1, in step 301, flatness information across substrate 101 is obtained using metrology sensor 112 and/or the substrate scale metrology system using large apertures and/or the substrate scale metrology system using a single spot measuring sensor discussed above.

In step 302, a nanometer precise film thickness of polymer is ink-jetted onto the non-uniform substrate 101 to result in a substantially planar top surface using the nP3 process.

In step 303, the cured resist is etched back into substrate 101 using a dry etching process, such as method 200. In one embodiment, an intermediate or a series of intermediate films are present between the polymer and substrate 101. For example, an intermediate film may correspond to silicon dioxide on a diamond substrate. In such an embodiment, the polymer profile is first transferred into silicon dioxide using a fluorine chemistry at temperatures low enough to ensure polymer stability, for example 150° C. The profile can now be etched into diamond using an oxygen dominant chemistry with high etch rates by either heating substrate 101 or through a DC-bias or both.

In one embodiment, the etch back is performed using an open loop control or using spatial etch rate control as discussed above in connection with thermal actuation sub-system 113 and the nozzle array for spatially varying etch rates.

In one embodiment, steps 301-303 can be repeated multiple times until flatness within a desired range is obtained.

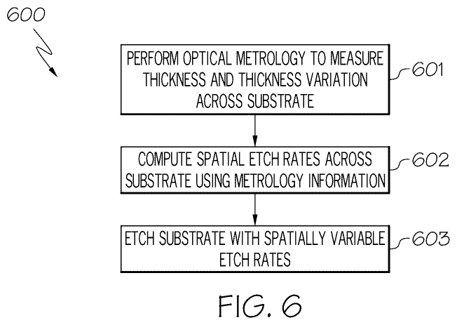

A substrate planarization process using spatial etch rate control is now discussed below in connection with FIG. 4.

FIG. 4 is a flowchart of a method 400 for performing substrate planarization using spatial etch rate control in accordance with an embodiment of the present disclosure.

Referring to FIG. 4, in conjunction with FIG. 1, in step 401, optical metrology is performed continuously or intermittently or once at the beginning and once at the end to measure the top surface profile variation across substrate 101.

In step 402, a control scheme is implemented in which the metrology information is used as feedback to control spatial etch rate actuators.

In step 403, the substrate is etched with spatially variable etch rates using techniques discussed above, such as uniform thermal actuation, spatially variable thermal actuation or spatially variable thermal actuation using a DMD system.

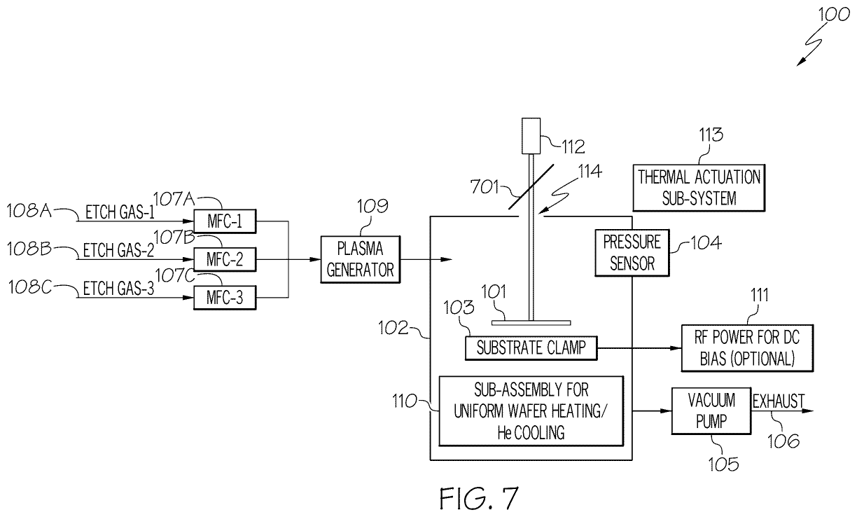

A processing for minimizing TTV using nP3 is now discussed below in connection with FIG. 5.

FIG. 5 is a flowchart of a method 500 for minimizing TTV using nP3 in accordance with an embodiment of the present disclosure.

Referring to FIG. 5, in conjunction with FIG. 1, in step 501, the substrate thickness and thickness variation across substrate 101 are measured using the techniques discussed above in connection with metrology sensor 112, the substrate scale metrology system using large apertures and the substrate scale metrology system using a single spot measuring sensor.

In step 502, the difference between the current and the desired profile is calculated and fed as input to the nP3 process which then inkjets a nanometer precise film thickness of polymer onto substrate 101.

In step 503, the cured resist is etched back into substrate 101 using a dry etching process, such as method 200. In one embodiment, an intermediate or a series of intermediate films are present between the polymer and substrate 101. For example, an intermediate film may correspond to silicon dioxide on a diamond substrate. In such an embodiment, the polymer profile is first transferred into silicon dioxide using a fluorine chemistry at temperatures low enough to ensure polymer stability, for example 150° C. The profile can now be etched into diamond using an oxygen dominant chemistry with high etch rates by either heating the substrate or through a DC-bias or both.

In one embodiment, the etch back is performed using an open loop control or using spatial etch rate control as discussed above in connection with thermal actuation sub-system 113 and the nozzle array for spatially varying etch rates.

Steps 501-503 can be repeated multiple times until flatness within a desired range is obtained.

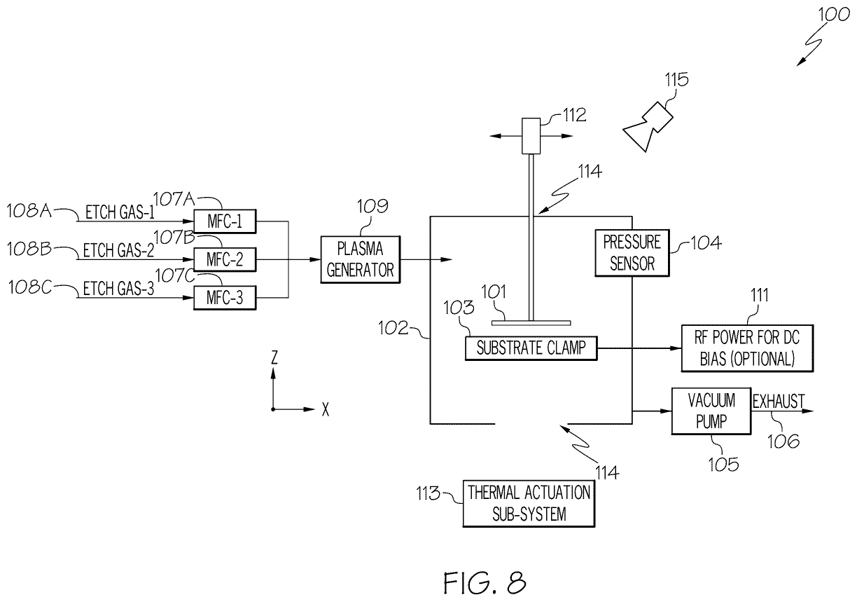

A discussion regarding minimizing TTV using spatial etch rate control is provided below in connection with FIG. 6.

FIG. 6 is a flowchart of a method 600 for minimizing TTV using spatial etch rate control in accordance with an embodiment of the present disclosure.

Referring to FIG. 6, in conjunction with FIG. 1, in step 601, optical metrology is performed continuously or intermittently or once at the beginning and once at the end to measure the thickness and thickness variation across substrate 101.

In step 602, a control scheme is implemented in which the metrology information is used as feedback to control spatial etch rate actuators by computing the spatial etch rates across substrate 101 using the metrology information.

In step 603, the die is etched using spatially variable etch rates using the techniques discussed above, such as uniform thermal actuation, spatially variable thermal actuation or spatially variable thermal actuation using a DMD system.

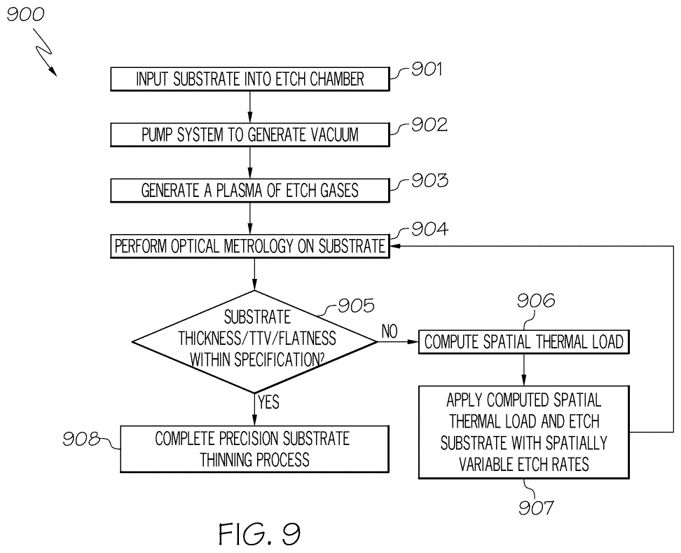

Referring now to FIG. 7, FIG. 7 illustrates an alternative architecture for PST equipment in comparison to the architecture presented in FIG. 1 in accordance with an embodiment of the present disclosure.

As shown in FIG. 7, a mirror 701 is used to direct light from the thermal actuation sub-system 113 onto substrate 101. In one embodiment, mirror 701 is placed on a moving stage. In one embodiment, a dichroic mirror or a beam splitter is used to allow the same optical path for metrology and thermal actuation. In another embodiment, the position and orientation of the metrology assembly, including metrology sensor 112, and/or the substrate scale metrology system using large apertures and/or the substrate scale metrology system using a single point sensor as discussed above, and thermal actuation sub-system 113 are interchanged. In one embodiment, metrology 112 is mounted on a metrology assembly for scanning substrate 101.

As shown in FIG. 7, a mirror 701 is used to direct the light from thermal actuation sub-system 113 onto substrate 101. In one embodiment, mirror 701 is placed on a moving stage. In one embodiment, a dichroic mirror or a beam splitter is used to allow the same optical path for metrology and thermal actuation. In another embodiment, the position and orientation of the metrology assembly, including metrology sensor 112 and thermal actuation sub-system 113 are interchanged. In one embodiment, metrology sensor 112 is mounted on a metrology assembly for scanning substrate 101.

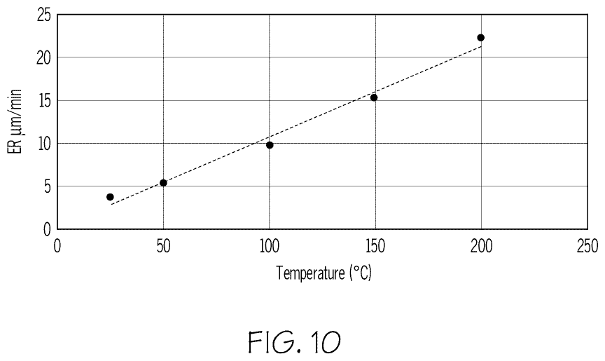

Referring now to FIG. 8, FIG. 8 illustrates an additional alternative architecture for PST equipment in accordance with an embodiment of the present disclosure.

As shown in FIG. 8, thermal actuation sub-system 113 is placed below process chamber 102. Furthermore, as shown in FIG. 8, substrate clamp 103 that is transparent to light from thermal actuation sub-system 113 is used. In another embodiment either or both the metrology sub-system using metrology sensor 112 and thermal actuation sub-system 113 are placed inside vacuum chamber 102.

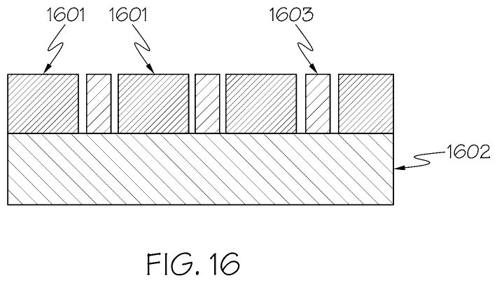

In one embodiment, there can be an intermediate film between the die and the base (see 1602 of FIG. 16), such that this film absorbs light from the thermal actuation sub-system 113. In one embodiment, this intermediate layer is carbon tape.

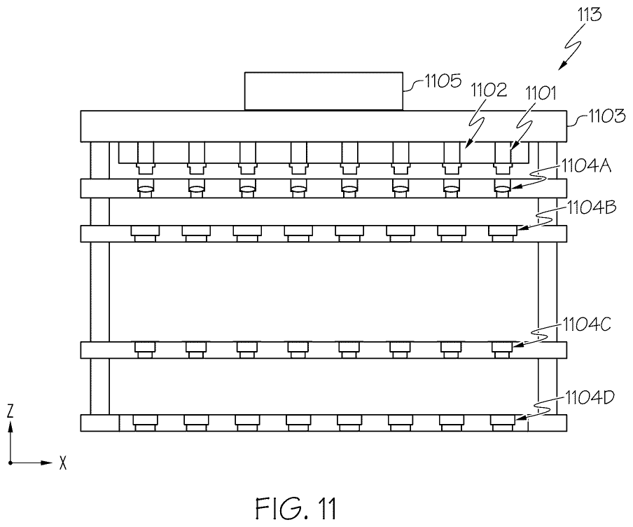

FIG. 9 is a flowchart of a method 900 for performing precision substrate thinning using spatial etch rate control in accordance with an embodiment of the present disclosure.

Referring to FIG. 9, in conjunction with FIGS. 1 and 7-8, in step 901, substrate 101 is inputted into etch chamber 102. In one embodiment, substrate 101 is diced. In another embodiment, substrate 101 is undiced. In one embodiment, the process time is reduced by reducing the thickness of the input substrate 101 using processes, such as wafer grinding and polishing.

In step 902, once substrate 101 is placed inside etch chamber 102, chamber 102 is pumped down to generate a vacuum.

In step 903, a plasma of etch gases 108 is generated. For example, in one embodiment, gases 108 suitable to etch the specific substrate material are injected inside chamber 102. In one embodiment, MFCs 107 are used to control the mass flow rate of the input gasses 108. In one embodiment, plasma is ignited following which substrate 101 is etched.

In step 904, the thickness and/or thickness variation across substrate 101 are measured. In one embodiment, a metrology system, including metrology sensor 112, is used to measure the thickness and/or thickness variation of substrate 101. In one embodiment, the measurement is performed continuously or intermittently. In one embodiment, the measurement is performed once in the beginning and once at the end.

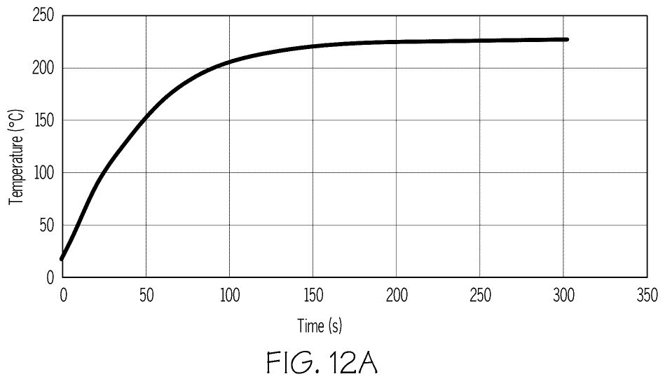

It is noted that etch rates may vary with temperature as shown in FIG. 10. FIG. 10 depicts the variation in etch rates as a function of temperature for silicon in accordance with an embodiment of the present disclosure.

Returning to FIG. 9, in conjunction with FIGS. 1, 7-8 and 10, in step 905, a determination is made as to whether substrate 101 has achieved the desired specification. In one embodiment, the desired specification refers to one or more of the following: a desired thickness, a desired TTV and a desired top surface flatness of the substrate.

If the desired specification has not been achieved, then, in step 906, the required spatial thermal load for substrate 101 is computed.

In one embodiment, spatially variable etch rates can be induced by generating a spatially variable temperature profile on substrate 101. In one embodiment, the thickness variation obtained from the metrology sub-system is used to calculate the spatial temperature profile (thermal load for substrate 101). In one embodiment, the desired temperature profile is generated by varying heat input from the illumination source on different parts of substrate 101. Techniques, such as pulse width modulation (PWM), can be used for such a purpose.

In step 907, the computed spatial thermal load is applied using thermal actuation sub-system 113 and substrate 101 is etched with spatially variable etch rates.

In one embodiment, spatially variable etch rates are generated by varying the concentration of etch gases 108 or the plasma power across the surface of substrate 101. In one embodiment, substrate 101 is cooled by injecting gases 108, such as N₂ or Ar, into process chamber 102 with plasma generator 109 switched off. In one embodiment, substrate 101 is cooled using backside He cooling. The process of metrology and thermal actuation is repeated until the thickness and TTV of substrate 101 are within specification.

After applying the computed spatial thermal load using thermal actuation sub-system 113, the thickness and/or thickness variation across substrate 101 is measured in step 904.

Returning to step 905, if, however, the desired specification has been achieved, then, in step 908, the precision substrate thinning process is completed.

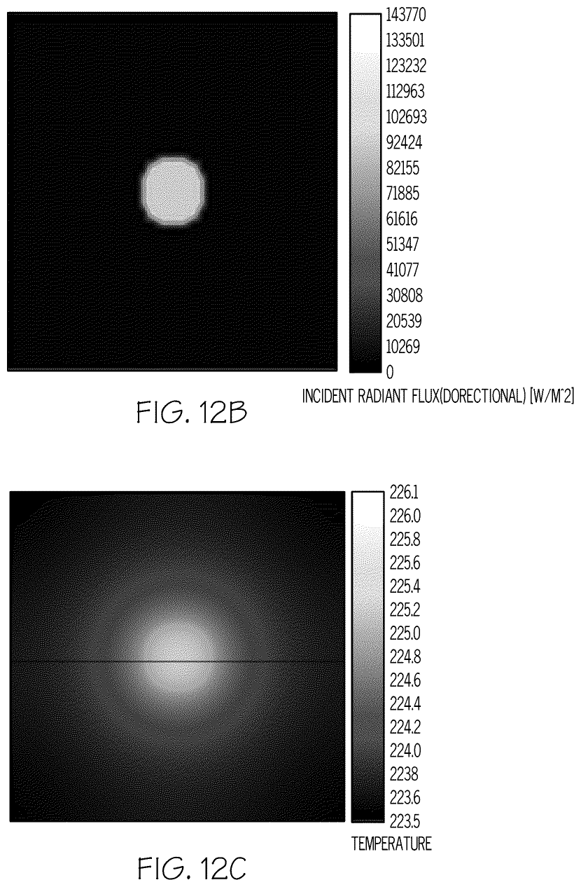

FIG. 11 illustrates an embodiment of the present disclosure of thermal actuation sub-system 113.

As shown in FIG. 11, thermal actuation sub-system 113 includes multiple high powered illumination sources including, but not limited to, laser diodes 1101 (LDs) or LEDs assembled in a two-dimensional matrix configuration. In one embodiment, LDs 1101 are mounted on a printed circuit board (PCB) 1102. In one embodiment, in order to remove heat from these LDs 1101, a heat sink is used. As shown in FIG. 11, a water-cooled metal plate 1103 is used as a heat sink.

In one embodiment, PCB 1102 has thermal vias to provide a thermal pathway from the laser diodes 1101 to heat sink 1103. In one embodiment, PCB 1102 is made of standard PCB materials, such as, but not limited to, epoxy resins. In one embodiment, insulated metal substrate (IMS) PCBs 1102 are used to improve thermal conduction between heat sink 1103 and LDs 1101.

In one embodiment, a stack of optical components including, but not limited to, lenses 1104A-1104D (identified as “Lens 1,” “Lens 2,” “Lens 3,” and “Lens 4,” respectively), apertures, and reflectors are used to capture light from the illumination sources and focus them onto substrate 101. One such instance is depicted in FIG. 11 where a stack of four lenses 1104A-1104D is used for each laser diode 1101. Lenses 1104A-1104D may collectively or individually be referred to as lenses 1104 or lens 1104, respectively. In one embodiment, the position of these optical components is varied to achieve the desired focusing distance. In one embodiment, the whole assembly is mounted on an XY stage 1105 to prevent any blind pots due to the pitch of LD 1101.

It is noted that while 11 illustrates four lenses 1104 that thermal actuation sub-system 113 may include any number of lenses 1104. Furthermore, it is noted that thermal actuation sub-system 113 may include any number of laser diodes 1101.

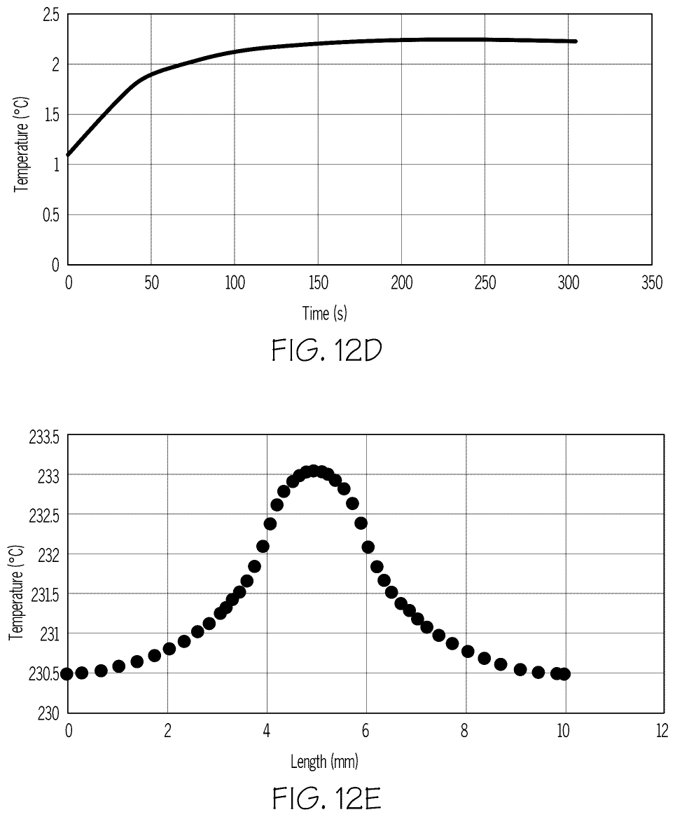

Referring now to FIGS. 12A-12E, in conjunction with FIG. 11, FIGS. 12A-12E illustrate the thermal simulation results for quantifying temperature across a die for a given heat input in accordance with an embodiment of the present disclosure.

In particular, FIG. 12A illustrates the results from a transient thermal simulation used to calculate temperature with respect to time, where PST is performed on a diced Si wafer, such that the dimension of each die is 10 mm×10 mm with a thickness of 0.75 mm. In one embodiment, the thermal load from a laser diode 1101 is simulated by applying a directional radiation of 0.45 W from a source of 2 mm diameter. The input radiation on the die is shown in FIG. 12B. As indicated in FIG. 12A, the temperature at the die center reaches about 200° C. in 100 seconds. FIG. 12C illustrates the two-dimensional temperature profile on the die in steady state. FIG. 12E illustrates the steady state temperature across the cross-section line in FIG. 12C. FIG. 12D illustrates the temperature difference between the die-center and the die-edge with respect to time. As shown in FIG. 12D, it can be concluded that temperature variation within a die is always less than 2.5° C.

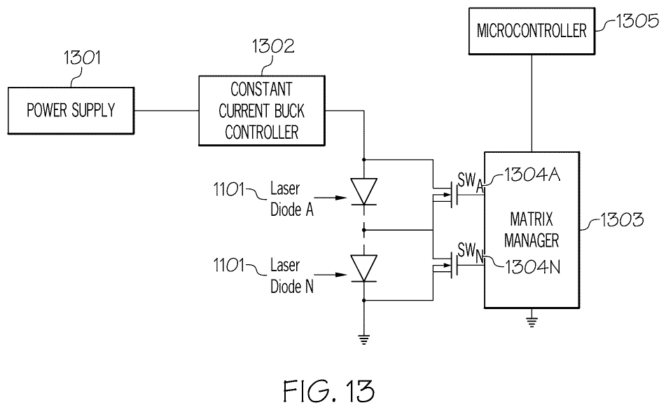

Referring now to FIG. 13, in conjunction with FIGS. 1 and 7-8, FIG. 13 is a methodology for the PWM control of the illumination sources used in one instance of thermal actuation sub-system 113 in accordance with an embodiment of the present disclosure. PWM is used in illumination sources to modify the thermal load to generate desired temperature profiles on substrate 101. A power supply 1301 is connected to a buck controller 1302, which outputs a constant current to LDs 1101A-1101N, where N is a positive integer number, and LEDs. Laser diodes 1101A-110N may collectively or individually be referred to as laser diodes 1101 or laser diode 1101, respectively. In one embodiment, LDs 1101 are connected to a matrix manager 1303 which consists of switches 1304A-1304N (identified as “SW_{A} . . . SW_{N},” where N is a positive integer number) that can be independently programmed to bypass the LD 1101 across that switch by microcontroller 1305. Switches 1304A-1304N may collectively or individually be referred to as switches 1304 or switch 1304, respectively. In one embodiment, LD 1101 can be fully on, fully off or dimmed using PWM.

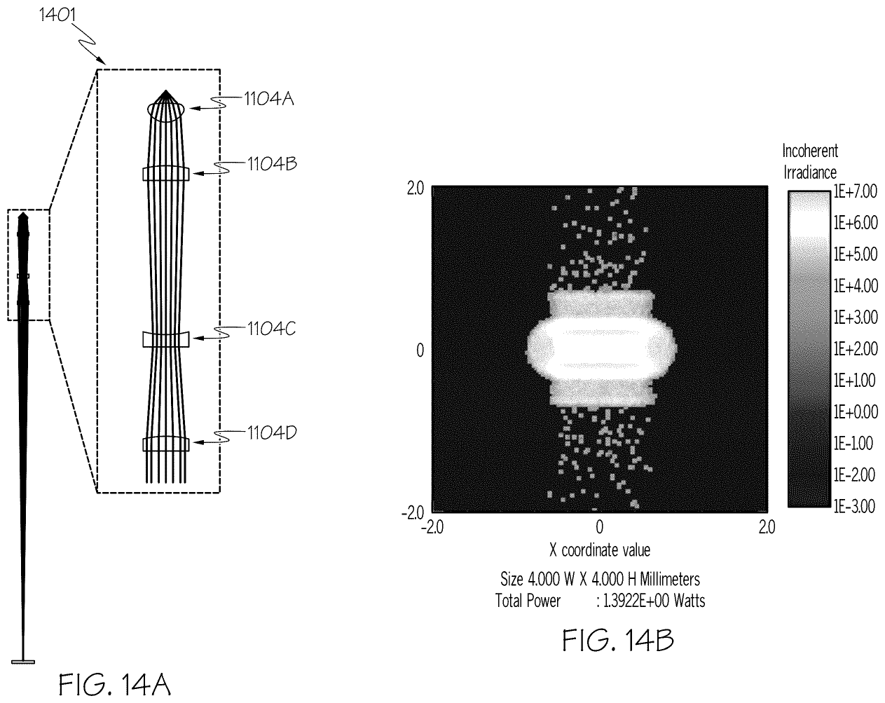

Referring now to FIGS. 14A-14B, FIGS. 14A-14B illustrate simulation and experimental results of the optical lens stack to focus diverging light from a laser diode in accordance with an embodiment of the present disclosure.

Illumination sources, such as LDs 1101 and LEDs, typically give out diverging light. In one embodiment, optical components are used to capture this diverging light and focus it onto substrate 101 as a small spot. In one embodiment, optical components, including, but not limited to, aspheric lenses, concave lenses, convex lenses, plano-concave lenses, plano-convex lenses, freeform lenses, parabolic reflectors, ellipsoidal reflectors, optical fibers and their combination are used for this purpose. In one embodiment, optical components have suitable coatings to enhance light transmission. FIG. 14B illustrates the simulation results for an instance of such an optical assembly 1401 presented in FIG. 14A, where light from the laser diode is focused on a substrate, such as substrate 101 of FIG. 1, 400 mm away. Separation between lenses 1104 can be modified to adjust the focusing distance. In one embodiment, optical assembly 1401, as shown in FIG. 14A, consists of an illumination source, such as a 1.6 W, 447 nm laser diode with a divergence beam angle of 56°, a first lens (Lens 1) 1104A (aspheric lens), a second lens (Lens 2) 1104B (plano convex lens with a curvature radius of 20.67 mm), a third lens (Lens 3) 1104C (plano concave lens with a curvature radius of 21.19 mm) and a fourth lens (Lens 4) 1104D (plano convex lens with a curvature radius 25.48 mm).

In one embodiment, lenses 1104 of optical assembly 1401 have a MgF₂ anti-reflective coating. FIG. 14B depicts the resultant illumination profile on a 4 mm×4 mm die. As shown in FIG. 14B, FIG. 14B suggests that the die receives 1.39 W of power thereby indicating an efficiency of ˜87%.

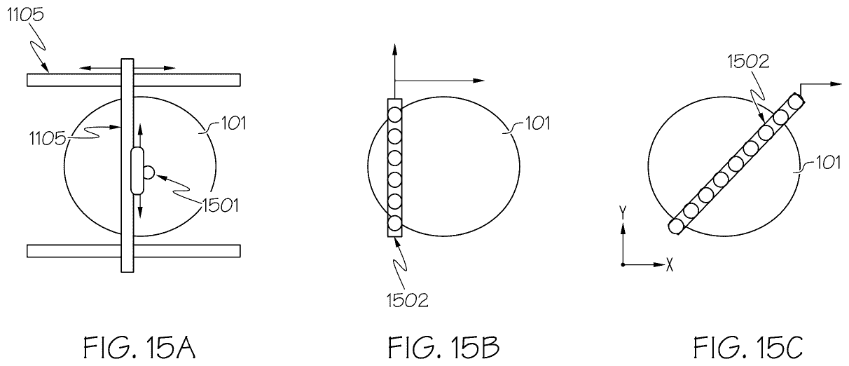

Referring now to FIGS. 15A-15C, FIGS. 15A-15C illustrate substrate scale metrology using single point sensors in accordance with an embodiment of the present disclosure.

In cases where the sensing area is smaller than substrate 101, various techniques can be used as illustrated in FIGS. 15A-15C to scan the entire substrate 101. As shown in FIG. 15A, a single sensor 1501 is mounted on an XY stage 1105. As shown in FIG. 15B, an array of sensors 1502 is mounted on XY stage 1105 to reduce the metrology time. In another embodiment, array of sensors 1502 is mounted on a linear stage or a rotary stage. FIG. 15C illustrates a configuration in which array of sensors 1502 is placed at an angle with respect to the direction of motion which helps in achieving a lower effective pitch. In such an embodiment, the metrology may potentially be reduced to a single scan in one direction. Other configurations, including, but not limited to, VPM, rotary stages, etc. may also be used.

Referring now to FIG. 16, FIG. 16 illustrates the inter-die features to address edge non-uniformities in accordance with an embodiment of the present disclosure.

With diced substrates there is a possibility of thickness variation and non-uniformities around the edges of the die due to lateral etch. In one embodiment, the principles of the present disclosure address these edge non-uniformities by having features between the dies as shown in FIG. 16. As illustrated in FIG. 16, the substrate consists of discrete dies 1601, which can be from a variety of electronic or optical materials. Base 1602, upon which these discrete dies 1601 are placed, can be a polymer base, a tape frame, a glass carrier, a sapphire carrier, a transparent carrier, a silicon carrier, a silicon carbide carrier, etc. By adjusting the geometry of inter-die features 1603, it is possible to influence the amount of etch species in the kerf and tune the process from edge fast to edge slow. In one embodiment, inter-die features 1603 are made with materials including, but not limited to, polymers, silicon dioxide, silicon carbide, silicon nitride, alumina, copper, titanium and titanium oxide.

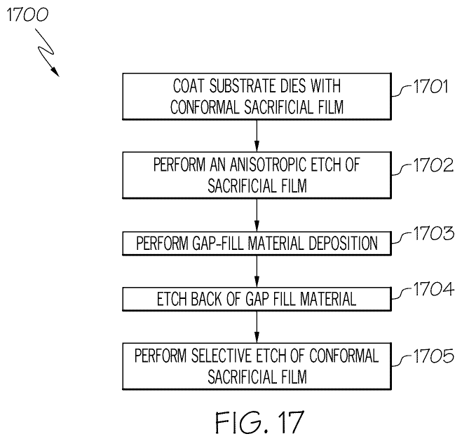

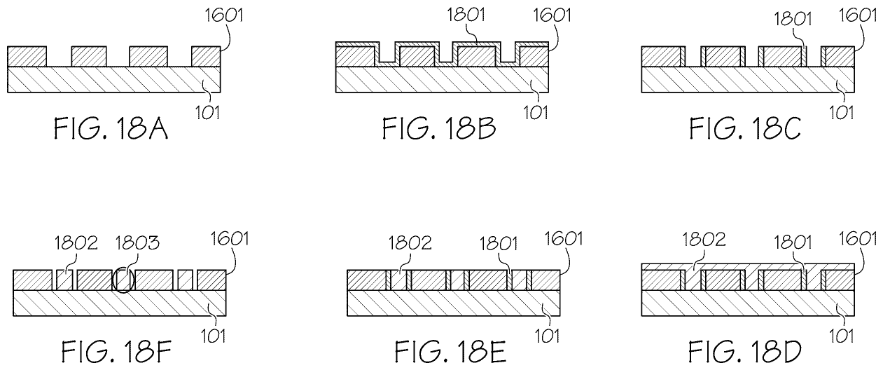

FIG. 17 is a flowchart of a method 1700 for generating inter-die features 1603 in accordance with an embodiment of the present disclosure. FIGS. 18A-18F depict the cross-sectional views for generating inter-die features 1603 using the steps described in FIG. 17 in accordance with an embodiment of the present disclosure.

Referring to FIG. 17, in conjunction with FIGS. 18A-18F, in step 1701, a conformal sacrificial layer 1801 is coated on substrate dies 1601 and exposed portions of substrate 101 as shown in FIGS. 18A-18B. In one embodiment, coating processes include, but not limited to, chemical vapor deposition, plasma enhanced chemical vapor deposition, low pressure chemical vapor deposition, flowable chemical vapor deposition and atomic layer deposition. In one embodiment, conformal sacrificial film 1801 is one or more of the following: an oxide, silicon oxide, aluminum oxide, silicon carbide, silicon nitride, Fluro-polymer, polymer, photoresist, carbon and adhesive.

In step 1702, an anisotropic etch of sacrificial film 1801 is performed using processes including, but not limited to, reactive-ion-etching as shown in FIG. 18C. For example, as shown in FIG. 18C, the top portion of the sacrificial film 1801 residing on the top surface of substrate dies 1601 and the top portion of the sacrificial film 1801 residing on the top surface of substrate 101 are etched away.

In step 1703, a gap fill material is deposited on the exposed portions of substrate 101 (as well as the top surface of substrate dies 1601) as shown in FIG. 18D. In one embodiment, photoresist 1802 (e.g., polymer) is deposited using a process, such as via spin-coating or ink-jetting. In another embodiment, gap fill material consists of one or more of the following: an oxide, silicon oxide, aluminum oxide, silicon carbide, silicon nitride, Fluro-polymer, polymer, photoresist, carbon and adhesive.

In step 1704, the top layer of gap fill material 1802 (residing on the top surface of substrate dies 1602) is removed as shown in FIG. 18E.

In step 1705, the remaining conformal sacrificial film 1801 is removed using an etch process thereby forming inter-die features 1803 as shown in FIG. 18F.

In one embodiment, the desired width of inter-die features 1803 is obtained by adjusting the thickness of the conformal sacrificial film (SiO₂) 1801 in step 1701.

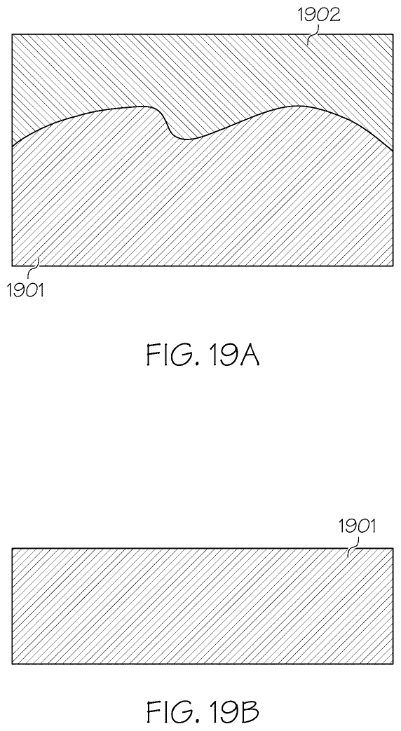

Referring now to FIGS. 19A-19B, FIGS. 19A-19B illustrate an exemplary process for profile correcting using nP3 in accordance with an embodiment of the present disclosure.

As shown in FIG. 19A, the original substrate 1901 is coated with polymer film 1902. In one embodiment, the material of the original substrate 1901 is silicon. In one embodiment, the top surface profile of substrate 1901 is measured using a metrology system. The nP3 process uses this information to inkjet a nanometer precise, planarized film 1902 of polymer onto the non-uniform substrate 1901. This planarized profile is now transferred to the original substrate 1901 through etch back as shown in FIG. 19B.

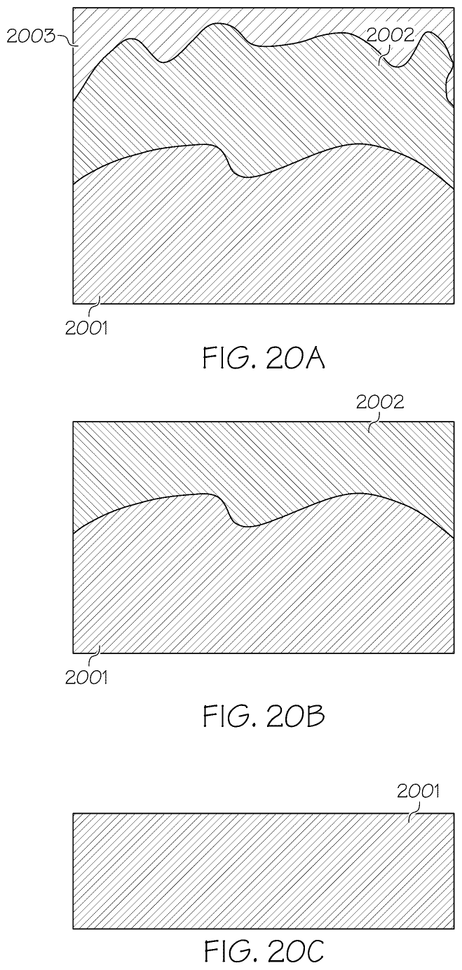

Referring now to FIGS. 20A-20C, FIGS. 20A-20C illustrate a process for profile correction using an intermediate film in accordance with an embodiment of the present disclosure.

As shown in FIG. 20A, substrate (original substrate) 2001 is coated with an intermediate film 2002 and a polymer film 2003. As further shown in FIG. 20A, intermediate film 2002 is used between substrate 2001 and polymer film 2003. In such an embodiment, the profile is first transferred onto intermediate film 2002 as shown in FIG. 20B at temperatures low enough to ensure polymer stability. FIG. 20C illustrates the profile transferred from intermediate film 2002 onto substrate 2001. In particular, this profile can now be etched into the material of substrate 2001 using high temperatures or DC-bias to enhance etch rates as shown in FIG. 20C.

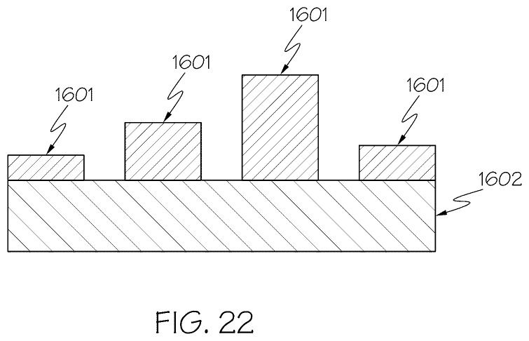

Referring now to FIG. 21, in conjunction with FIGS. 1 and 7-8, FIG. 21 is a flowchart of a method 2100 for PST using nP3 in accordance with an embodiment of the present disclosure.

In step 2101, the thickness and thickness variation across substrate 101 is measured.

In step 2102, based on such a measurement, the spatial thickness profile of the polymer to be used as coating to minimize the TTV is calculated. In one embodiment, the required thickness of the polymer depends on the etch selectivity of the polymer with respect to substrate 101.

In step 2103, a polymer film of the calculated thickness (“profile”) is then coated on substrate 101, such as via an inkjet, using the nP3 process.

In step 2104, the profile is then etched back into the original substrate.

In one embodiment, an intermediate layer, such as shown in FIGS. 20A-20B, may also be present. In one embodiment, the process discussed above (steps 2101-2014) is repeated until the thickness variation in substrate 101 is within specification.

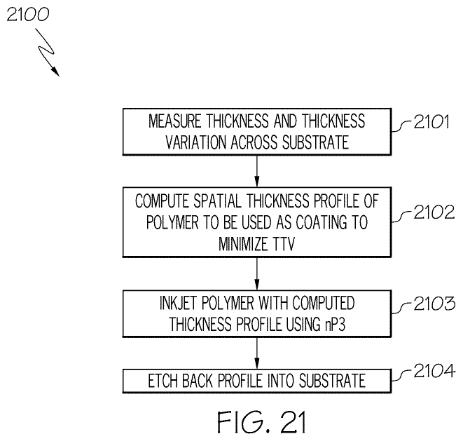

Referring now to FIG. 22, FIG. 22 illustrates a substrate having dies of different thickness in accordance with an embodiment of the present disclosure.

PST can also be used for substrate thinning when the desired thickness may be different for each or a group of substrate dies 1601. As shown in FIG. 22, FIG. 22 depicts such a scenario in which the desired thickness of substrate dies 1601 are different. In one embodiment, the desired thickness of substrate dies 1601 are different using method 900, such that the variable thermal load is applied on dies 1601 to achieve the desired different die thicknesses. In another embodiment, method 2100 may be used such that the thickness profile of the polymer film to be coated accounts for the different thicknesses on each substrate die 1601.

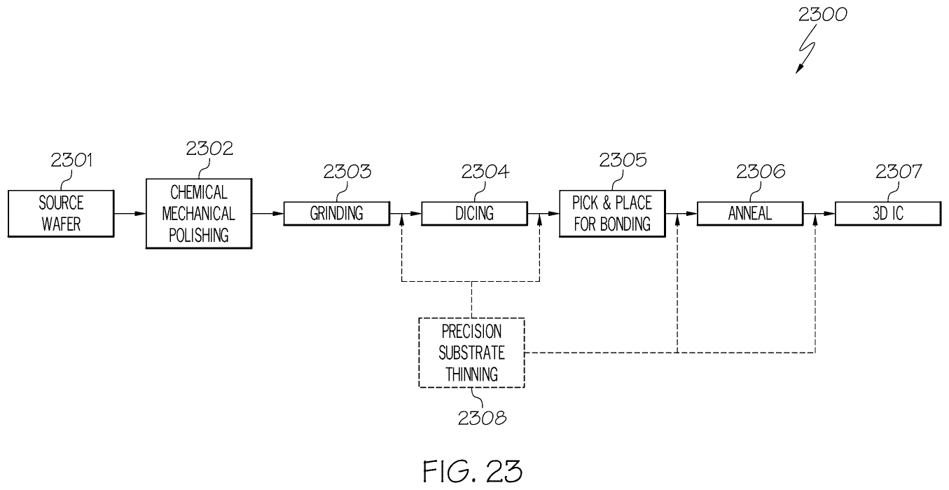

Referring now to FIG. 23, FIG. 23 illustrates an exemplary method 2300 for three-dimensional (3D) integration, one of the use cases for PST, in accordance with an embodiment of the present disclosure.

As depicted in FIG. 23, method 2300 includes a source wafer 2301 in which material on the surface of source wafer 2301 is mechanically removed using chemical mechanical polishing 2302. The source wafer may then be grounded down to a desired thickness via grinding 2303. The source wafer may then be cut or diced into dies via dicing 2304 followed by picking and placing the dies for bonding 2305. After picking and placing the dies for bonding 2305, annealing 2306 is performed thereby forming a three-dimensional (3D) integrate circuit (IC) 2307.

As shown in FIG. 23, PST (precision substrate thinning) 2308 can be accommodated in different stages of method 2300. PST can be performed before or after dicing 2304, after pick and place 2305 or after annealing 2306. In one embodiment, the input substrate to PST may have variations based on where PST is accommodated in method 2300. The variations can be the substrate being diced or undiced as well as the base film being of different material among others.

In one embodiment, PST, using process 900, is performed after dicing and is further performed after pick & place assembly onto the product substrate 101. In such an embodiment, the PST is used to improve the TTV of the dies to be below one of the following: 1 μm, 500 nm, 200 nm, 100 nm, 50 nm, 25 nm and 10 nm. Furthermore, in such an embodiment, PST is performed for the dies to achieve a final mean thickness below one of the following: 100 μm, 50 μm, 10 μm, 5 μm and 1 μm.

In another embodiment, PST, using process 900, is performed after dicing and is further performed prior to pick and place assembly. In such an embodiment, PST is performed on one or more of the following carrier substrates: tape frame, glass, sapphire and silicon carbide. In such an embodiment, the PST is used to improve the TTV of the dies to be below one of the following: 1 μm, 500 nm, 200 nm, 100 nm, 50 nm, 25 nm and 10 nm. Furthermore, in such an embodiment, PST is performed for the dies with a thickness below one of the following: 100 μm, 50 μm, 10 μm, 5 μm and 1 μm.

In another embodiment, PST, using process 2100, is performed prior to dicing. In such an embodiment, PST is performed on one or more of the following carrier substrates: tape frame, glass, sapphire and silicon carbide. In such an embodiment, the PST is used to improve the TTV of the substrate to be below one of the following: 1 μm, 500 nm, 200 nm, 100 nm, 50 nm, 25 nm and 10 nm. In one embodiment, a multi-step approach is utilized, where a first step process is performed at a higher etch rate and one or more subsequent processes are performed at lower etch rates.

In one embodiment, one or more substrate thinning steps using process 2100 are performed prior to dicing followed by performing one or more substrate thinning steps using process 900 after dicing.

Table 1, shown below, describes the various potential choices for etch gases and process conditions that can be utilized for specific substrate materials in accordance with an embodiment of the present disclosure.

TABLE 1

| | | Etch | | |
|---|---|---|---|---|
| S. | Die | Config- | | |
| No. | Material | urations | Process Gases | Temperature* |
| 1 | Silicon | ICP or | One or more of (CF₄, | Optionally |
| | | ECR | C₂F₆, CHF₃, SF₆, NF₃), | increased |
| | | or RPS or | with optionally Ar, and | temperature, |
| | | CCP with | with optionally O₂ | for example |
| | | or without | | >=150° C., |
| | | DC Bias | | or >=400° C., |
| | | | | or >=1,000° C. |
| 2 | Silicon | ICP or | One or more of (CF₄, | Optionally |
| | Carbide | ECR | C₂F₆, CHF₃, SF₆, NF₃), | increased |
| | | or RPS or | with optionally Ar, | temperature, |
| | | CCP with | optionally H₂ and | for example |
| | | or without | optionally O₂ | >=150° C., |
| | | DC Bias | | or >=300° C., |
| 3 | Silicon | ICP or | One or more of (CF₄, | Optionally |
| | Nitride | ECR | C₂F₆, CHF₃, SF₆, NF₃), | increased |
| | | or RPS or | with optionally O₂ | temperature, |
| | | CCP with | | for example |
| | | or without | | >=150° C., |
| | | DC Bias | | or >=300° C., |
| | | | | or >=1,000° C. |
| 4 | Silicon | ICP or | One or more of (CF₄, | Optionally |
| | Oxide | ECR | CHF₃, C₂F₆, SF₆, NF₃), | increased |
| | | or RPS or | with optionally Ar | temperature, |
| | | CCP with | | for example |
| | | or without | | >=150° C., or |
| | | DC Bias | | >=300° C., or |
| | | | | >=1,000° C. |
| 5 | Diamond | ICP or | O₂, with optionally Ar, | Optionally |
| | | ECR | and optionally one or | increased |
| | | or RPS or | more of (SF₆, CF₄,) | temperature, |
| | | CCP with | | for example |
| | | or without | | >=150° C., |
| | | DC Bias | | or >=900° C. |
| 6 | Gallium | ICP or | One or more of (Cl₂, | Optionally |
| | Nitride | ECR | CHF₃, SiCl₄, ICl, IBr) | increased |
| | | or RPS or | with optionally H₂ and | temperature, |
| | | CCP with | optionally Ar | for example |
| | | or without | | >=150° C., |
| | | DC Bias | | or >=900° C. |
| 7 | Boron | ICP or | One or more of (BCl₃, | Optionally |
| | Nitride | ECR | Cl₂, SF₆, CF₄) with | increased |
| | | or RPS or | optionally H₂ | temperature, |
| | | CCP with | optionally N₂, and | for example |
| | | or without | optionally Ar | >=150° C., |
| | | DC Bias | | or >=900° C. |
| 8 | Titanium | ICP or | One or more of (CF₄, | Optionally |
| | Oxide | ECR | CHF₃, SF₆, NF₃, CCl₄, | increased |
| | | or RPS or | BCL₃) with optionally | temperature, |
| | | CCP with | O₂ and with | for example |
| | | or without | optionally Ar | >=150° C., |
| | | DC Bias | | or >=900° C. |

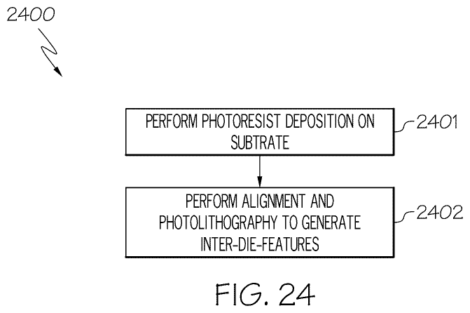

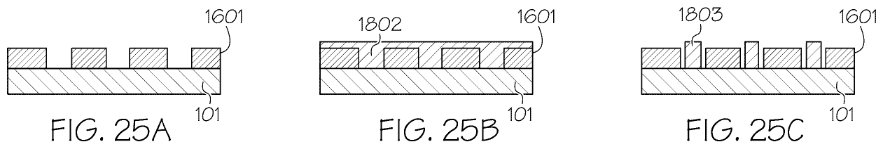

FIG. 24 is a flowchart of an alternative method 2400 for generating inter-die features in accordance with an embodiment of the present disclosure. FIGS. 25A-25C depict the cross-sectional views for generating inter-die features using the steps described in FIG. 24 in accordance with an embodiment of the present disclosure.

Referring to FIG. 24, in conjunction with FIGS. 25A-25C, in step 2401, a deposition of photoresist 1802 (e.g., polymer) onto substrate dies 1601 and substrate 101 is performed using a process, such as spin-coating or ink-jetting, as shown in FIGS. 25A-25B.

In step 2402, an alignment and photolithography are performed to generate inter-die features 1803 as shown in FIG. 25C.

As a result of the foregoing, the principles of the present disclosure provide a means for improving the precision for substrate thinning.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for thinning a group of two or more dies, the method comprising:
introducing an etch gas chemistry into a plasma generator;
generating a plasma using said etch gas chemistry by said plasma generator;
etching said two or more dies placed within an etch chamber to thin said two or more dies until said two or more dies achieve a desired thickness using said plasma; and
implementing a spatially variable closed loop control of etch rates of said etching to provide spatially variable etch rates during said thinning of said two or more dies.

2. The method as recited in claim 1, wherein said plasma is generated inside an etch chamber.

3. The method as recited in claim 1, wherein said plasma is generated in a remote source.

4. The method as recited in claim 1, wherein said two or more dies are located on a base.

5. The method as recited in claim 4, wherein said base is a tape frame.

6. The method as recited in claim 4, wherein said base is a carrier wafer.

7. The method as recited in claim 1, wherein said closed loop control of etch rates of said etching utilizes a metrology module.

8. The method as recited in claim 7, wherein said metrology module is used to measure die thickness and thickness variation using low coherence interferometry, ellipsometry, phase-shifting interferometry and moiré interferometry.

9. The method as recited in claim 7, wherein said metrology module is used to measure topography using one or more of the following: laser interferometry, optical emission interferometry and Fizeau interferometry.

10. The method as recited in claim 7, wherein said metrology module moves relative to said two or more dies by using one or more of the following: a linear stage, a rotary stage and a variable pitch mechanism.

11. The method as recited in claim 1, wherein said spatially variable etch rates are induced using a thermal actuation module comprising one or more of the following: resistive heating elements, radiative heating elements, illumination sources and a digital micromirror array.

12. The method as recited in claim 11, wherein said thermal actuation module comprises optical components to focus light from said illumination sources to said two or more dies.

13. The method as recited in claim 12, wherein said thermal actuation module has relative motion with respect to said two or more dies using one or more of the following: a linear stage, a rotary stage and a variable pitch mechanism.

14. The method as recited in claim 1, wherein said two or more dies are placed on a DC-biasing electrode to enhance etch rates.

15. The method as recited in claim 1 further comprising:
correcting flatness or total thickness variation (TTV) errors in said two or more dies.

16. The method as recited in claim 15, wherein a final TTV of said two or more dies is below one of the following: 200 nm, 100 nm, 50 nm, 25 nm and 10 nm.

17. The method as recited in claim 15, wherein a final TTV across said two or more dies is below one of the following: 200 nm, 100 nm, 50 nm, 25 nm and 10 nm.

18. The method as recited in claim 1, wherein a final mean thickness of said two or more dies is below one of the following: 50 μm, 10 μm, 5 μm and 1 μm.

19. The method as recited in claim 1, wherein said two or more dies have inter-die features to address edge non-uniformities.

20. The method as recited in claim 19, wherein a height and a width of said inter-die features is adjusted to tune etch rates around die edges.

21. The method as recited in claim 1, wherein said spatially variable etch rates are determined using an algorithm executed in one or more of the following locations: a local computer, a remote computer and a cloud-based computer.

22. The method as recited in claim 1 further comprising:
implementing nP3 to perform TTV reduction and planarization for said two or more dies.

23. A system for thinning a group of two or more dies using the method of claim 1.
